(19) United States
(12) Patent Application Publication
(10) Pub. No.: US 2024/0267032 A1
(43) Pub. Date: Aug. 8, 2024

(54) PHASE SHIFTER AND PHASE SHIFTING METHOD

(71) Applicant: SMARTER MICROELECTRONICS (GUANG ZHOU) CO., LTD., Guangzhou (CN)

(72) Inventors: Yangyang PENG, Guangzhou (CN); Ping LI, Guangzhou (CN); Yang LI, Guangzhou (CN)

(73) Assignee: SMARTER MICROELECTRONICS (GUANG ZHOU) CO., LTD., Guangzhou (CN)

(21) Appl. No.: 18/479,093

(22) Filed: Oct. 1, 2023

Related U.S. Application Data
(63) Continuation of application No. PCT/CN2022/121031, filed on Sep. 23, 2022.

(30) Foreign Application Priority Data
Sep. 23, 2021 (CN) 202111116105.X

(51) Int. Cl. H03H 11/16; H03F 3/19

(52) U.S. Cl. CPC H03H 11/16; H03F 3/19; H03F 2200/451

(57) ABSTRACT

A phase shifter includes an orthogonal signal generator and an adder; the output end of the orthogonal signal generator is connected with the input end of the adder, and the orthogonal signal generator is configured to generate a first orthogonal signal; the adder is configured to carry out an amplitude adjustment on the first orthogonal signal, and to carry out vector composing and phase compensation on the adjusted first orthogonal signal to obtain a first phase shift signal.

### CROSS-REFERENCE TO RELATED APPLICATIONS

This is a continuation of International Application No. PCT/CN2022/121031 filed on Sep. 23, 2022, which claims priority to Chinese Patent Application No. 202111116105.X field on Sep. 23, 2021. The disclosures of the above-referenced applications are hereby incorporated by reference in their entirety.

### BACKGROUND

In order to solve the problems of inconsistent output loads and poor phase shifting accuracy caused by the difference between multi-channel current of differential adder in multiphase phase shifter, in some implementations, the current value of multi-channel is manually adjusted until it returns to the desired phase, which needs extra debugging with a long debugging time and has an uncontrollable phase error.

### SUMMARY

The application relates to the technology of a phase shifter, in particular to a phase shifter and a phase shifting method.

Embodiments of the disclosure are intended to provide a phase shifter and a phase shifting method.

In a first aspect, embodiments of the disclosure provide a phase shifter including an orthogonal signal generator and an adder.

An output end of the orthogonal signal generator is connected with an input end of the adder, and the orthogonal signal generator is configured to generate a first orthogonal signal.

The adder is configured to adjust amplitude of the first orthogonal signal, and to carry out vector composing and phase compensation on the adjusted first orthogonal signal to obtain a first phase shift signal.

In an embodiment, the adder comprises multiple signal processing units and an adder unit.

An input end of the signal processing units is connected with the output end of the orthogonal signal generator, an output end of the signal processing units is connected to an input end of the adder unit, and the signal processing units are configured to carry out amplitude adjustment and phase compensation on the first orthogonal signal.

The adder unit is configured to carry out additive operation on the first orthogonal signal after processing to obtain the first phase shift signal.

In an embodiment, the signal processing units include an adjusting unit, and a phase compensation unit sequentially connected.

The adjusting unit is configured to carry out amplitude adjustment on the first orthogonal signal.

The phase compensation unit is configured to carry out phase compensation on the first orthogonal signal after the amplitude adjustment.

In an embodiment, the signal processing units include a phase compensation unit, and an adjusting unit sequentially connected.

The phase compensation unit is configured to carry out phase compensation on the first orthogonal signal.

The adjusting unit is configured to carry out amplitude adjustment on the first orthogonal signal after the phase compensation.

In an embodiment, the phase compensation unit has a compensation structure of at least one of “pi (π) type”, “T type”, or “L type”.

In an embodiment, the phase compensation unit includes at least one of an inductor or a capacitor.

The phase compensation unit further includes at least one control switch in the case that every device in the phase compensation unit has a fixed reactance value.

In an embodiment, a compensation phase of the phase compensation unit is adjustable based on a gain and/or an output power of an amplifier connected to the adder unit.

In an embodiment, the adjusting unit includes an orthogonal path selecting unit and a variable gain amplifier.

An input end of the orthogonal path selecting unit is connected to the output end of the orthogonal signal generator, and the orthogonal path selecting unit is configured to select a part of the first orthogonal signal.

An input end of the variable gain amplifier is connected with an output end of the orthogonal path selecting unit, and the variable gain amplifier is configured to adjust amplitude of the selected part of the first orthogonal signal.

In an embodiment, the variable gain amplifier is a differential amplifier.

In an embodiment, the first phase shift signal is a differential signal.

In an embodiment, the first orthogonal signal comprises multi-channel sub-signals.

In a second aspect, embodiments of the disclosure provide an amplifier assembly, which includes a phase shifter according to any one of the first aspect, and an amplifying circuit connected with an output end of the phase shifter.

In an embodiment, the amplifying circuit includes a first transformer, an amplifier and a second transformer.

The first transformer is configured to carry out isolation and first power conversion on the output end of the phase shifter to obtain a first power signal.

The amplifier is configured to carry out second power conversion on the first power signal to obtain a second power signal.

The second transformer is configured to carry out isolation and third power conversion on an output end of the amplifier to obtain a second phase shift signal.

In a third aspect, embodiments of the disclosure provide a phase shifting method, which includes the following operations.

A first orthogonal signal is generated by an orthogonal signal generator.

Amplitude of the first orthogonal signal is adjusted by an adder, and vector composing and phase compensation are carried out on the adjusted first orthogonal signal by the adder to obtain a first phase shift signal.

In a forth aspect, embodiments of the disclosure also provide a phase shifting method, which includes the following operations.

A preset phase shift angle is acquired.

A control signal corresponding to the preset phase shift angle is determined.

An adder in a phase shifter is controlled to carry out phase compensation based on the control signal, so that the adder outputs a radio frequency signal having a same phase shift angle of a horizontal I path and a vertical Q path.

In an embodiment, the operation that a control signal corresponding to the preset phase shift angle is determined includes the following operations.

A difference between a phase shift angle output by the phase shifter and the preset phase shift angle is acquired in real time.

The control signal corresponding to the preset phase shift angle is generated based on the difference. Or,
a mapping table of the phase shift angle and a compensation angle is acquired.

The compensation angle corresponding to the preset phase shift angle is determined based on the mapping table.

A control signal corresponding to the compensation angle is determined as the control signal corresponding to the preset phase shift angle.

In embodiments of the disclosure, since the controller in the phase shifter can generate a control signal for controlling the adder based on the preset phase shift angle, the adder can carry out vector composing and phase compensation on the first orthogonal signal based on the control signal, that is, the phase compensation can be automatically realized without manually adjusting the current values of multi-channel, so that the debugging time is short, and the phase error can be controlled.

It should be understood that the above general description and the following detailed description are exemplary and explanatory only and are not limiting to the disclosure.

### BRIEF DESCRIPTION OF THE DRAWINGS

The drawings, which are incorporated in and constitute a part of the specification, illustrate embodiments consistent with the disclosure and together with the description serve to explain the technical solution of the disclosure.

FIG. 1 is a component circuit diagram of an active phase shifter in some implementations;

FIG. 2 is a schematic diagram of the component structure of a phase shifter provided by embodiments of the disclosure;

FIG. 3 is a schematic diagram of the component structure of another phase shifter provided by embodiments of the disclosure;

FIG. 4 is a schematic diagram of the component structure of yet another phase shifter provided by embodiments of the disclosure;

FIG. 5 is a schematic diagram of the component structure of still another phase shifter provided by embodiments of the disclosure;

FIG. 6 is a implementation flowchart of a phase shifting method provided by embodiments of the disclosure;

FIG. 7 is a implementation flowchart of another phase shifting method provided by embodiments of the disclosure;

FIG. 8A is a component schematic diagram of a phase compensation unit provided by embodiments of the disclosure;

FIG. 8B is a schematic diagram of the component structure of a phase compensation unit provided by embodiments of the disclosure;

FIG. 8C is a schematic diagram of the component structure of another phase compensation unit provided by embodiments of the disclosure;

FIG. 8D is a schematic diagram of the component structure of yet another phase compensation unit provided by embodiments of the disclosure;

FIG. 8E is a circuit diagram of a phase compensation unit provided by embodiments of the disclosure; and

FIG. 9 is a component circuit diagram of an active phase shifter provided by embodiments of the disclosure.

### DETAILED DESCRIPTION

The disclosure will be further described in detail below with reference to the drawings and embodiments. It should be understood that the embodiments provided herein are intended to be explanatory only and are not intended to limit the disclosure. In addition, the embodiments provided below are a part of embodiments for implementing the disclosure, not all of the embodiments, and the technical solutions described in the embodiments of the disclosure can be implemented in any combination without conflict.

It should be noted that, in embodiments of the disclosure, terms “include”, “comprise” or any other variation thereof are intended to encompass non-exclusive inclusion, so that a method or equipment that includes a set of elements includes not only those explicitly recorded elements but also other elements that are not explicitly listed, or also elements inherent to implementation of a method or an equipment. In the absence of further limitations, an element defined by the phrase “includes a . . . ” does not preclude the existence of another relevant element in the method or equipment in which it is included (for example, an operation in the method for a unit in equipment, the exemplary unit may be a part of the circuit, processor, and program of software).

The term “and/or” herein is merely an association relationship describing associated objects, indicating that there can be three relationships, for example, U and/or W, which can mean that there are three situations: U alone, U and W simultaneously, and W alone. In addition, the term “at least one” herein means any one or any combination of at least two of the plurality, for example, including at least one of U, W, or V may means including any one or more elements selected from the set of U, W, and V.

A phase shifter is a device used to generate multi-phase signals, which is widely used in radio frequency systems. Phase shifters are mainly divided into active phase shifters and passive phase shifters. Herein, the active phase shifter is characterized by small area, flexibility and controllability, and in that it can generate gain, but its linearity is limited. The passive phase shifter is characterized by stable phase, high linearity, but large area and loss.

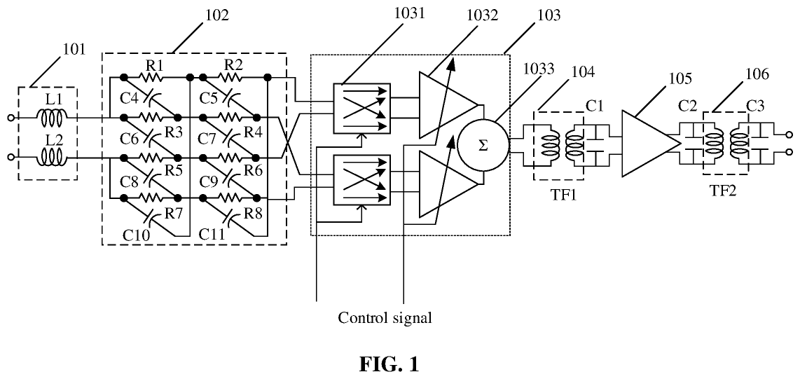

FIG. 1 is a component circuit diagram of an active phase shifter in some implementations. As shown in FIG. 1, the active phase shifter includes an inter stage matching network (IMN) 101, a poly phase filter (PPF) 102, an analog adder 103. Herein, a differential radio frequency signal is input to an input end of the IMN 101. The IMN 101 performs network matching on the input differential radio frequency signal, and input the differential radio frequency signal after network matching into the PPF 102. Four orthogonal signals (two positive output ends I+, Q+and two negative output ends I−, Q−) with same amplitude and a 90-degrees phase spacing are generated by the PPF 102, and the four orthogonal signals with same amplitude and a 90-degree phase spacing are input to the analog adder 103. The analog adder 103 performs vector composing on the four orthogonal signals with same amplitude and a 90-degree phase spacing in response to an external control signal, and outputs a radio frequency signal to a subsequent amplifier.

It can be understood that the two-order RC filter includes eight resistors R1 to R8 and eight capacitors C4 to C11. Herein, a series branch formed by series connection of R1 and R2 is connected between a first input end and a first output end (I+) of the two-order RC filter; a series branch formed by series connection of R3 and R4 is connected between the first input end and a second output end (Q+) of the two-order RC filter; a series branch formed by series connection of R5 and R6 is connected between a second input end and a third output end (I−) of the two-order RC filter; a series branch formed by series connection of R7 and R8 is connected between the second input end and a fourth output end (Q−) of the two-order RC filter; C4 is connected across two ends of R3, and the positive electrode of C4 is connected to the first input end; the negative electrode of C5 is connected to the second output end, and the positive electrode of C5 is connected to the common node of R1 and R2; the positive electrode of C6 is connected to the first input end, and the negative electrode of C6 is connected to the common node of R5 and R6; the negative electrode of C7 is connected to the third output end, and the positive electrode of C7 is connected to the common node of R3 and R4; C8 is connected across two ends of R7, and the positive electrode of C8 is connected to the second input end; the negative electrode of C9 is connected to the fourth output end, and the positive electrode of C9 is connected to the common node of R5 and R6; the positive electrode of C10 is connected to the second input end, and the negative electrode of C10 is connected to the common node of R1 and R2; the negative electrode of C11 is connected to the first output end, and the positive electrode of C11 is connected to the common node of R7 and R8.

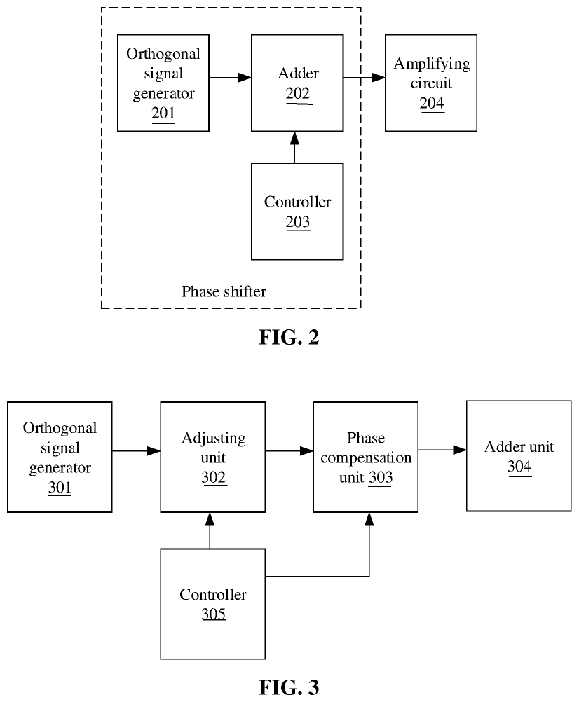

FIG. 2 is a schematic diagram of the component structure of an amplifier assembly provided by embodiments of the disclosure. As shown in FIG. 2, the amplifier assembly may include a phase shifter and an amplifying circuit 204. The phase shifter includes an orthogonal signal generator 201, an adder 202 and a controller 203.

The output end of the orthogonal signal generator 201 is connected with the input end of the adder 202, and the orthogonal signal generator 201 is configured to generate a first orthogonal signal.

The controller 203 is connected to the adder 202, and the controller 203 is configured to generate a control signal for controlling the adder 202 based on a preset phase shift angle.

The output end of the adder 202 is connected to the input end the amplifying circuit 204, and the adder 202 is configured to adjust the amplitude of the first orthogonal signal based on the control signal, and carry out vector composing and phase compensation on the adjusted first orthogonal signal to obtain a first phase shift signal.

The amplifying circuit 204 is configured to amplify the power of the first phase shift signal to obtain a second phase shift signal after power amplification.

In some possible embodiments, the first orthogonal signal may be four orthogonal signals (two positive output ends I+, Q+and two negative output ends I−, Q−) with same amplitude and a 90-degree phase spacing. The orthogonal signal generator 201 may be any generator capable of generating four orthogonal signals (two positive output ends I+, Q+ and two negative output ends I−, Q−) with same amplitude and a 90-degree phase spacing. For example, the orthogonal signal generator 201 may be a two-order RC filter.

In other embodiments, the first orthogonal signal may also be orthogonal signals with other number and/or other phase spacing. For example, the first orthogonal signal has eight sub-signals, and for another example, the phase spacing of the first orthogonal signal is 45 degrees.

In one possible embodiment, the controller 203 may be at least one of an application specific integrated circuit (ASIC), a digital signal processor (DSP), a digital signal processing device (DSPD), a programmable logic device (PLD), a field programmable gate array (FPGA), a central processing unit (CPU), a controller, a microcontroller, or a microprocessor. The controller 203 can generate a control signal for controlling the adder 202 corresponding to a preset phase shift angle. The preset phase shift angle may be determined according to the application scenario of the phase shifter. For example, in some application scenarios where the phase shifter needs to be shifted by 30 degrees, the corresponding preset phase shift angle is 30 degrees.

It should be noted that the controller may also be omitted in some embodiments. Alternatively, the adder can be controlled by a controller in other structures.

In one example, the adder 202 may include a vector composing circuit for performing vector composing and a phase compensation circuit for performing phase compensation. Correspondingly, the controller 203 may generate a control signal for the adder 202 to implement vector composing and a control signal for controlling the adder 202 to implement phase compensation respectively, that is, the controller 203 may generate control signals for at least two different purposes.

In one possible embodiment, the vector composing circuit may include an orthogonal path selecting unit, a VGA, and an adder unit sequentially connected. The phase compensation circuit may be located between the VGA and the adder unit; or, the phase compensation circuit may also be located between the orthogonal path selecting unit and the VGA.

In an embodiment, the amplifying circuit 204 may include multiple amplifying sub-circuits. For example, the amplifying circuit 204 may include a primary amplifying circuit, a secondary amplifying circuit and a tertiary amplifying circuit, in which the primary amplifying circuit or the tertiary amplifying circuit may be a transformer.

In an embodiment, the amplifying circuit may include a first transformer, an amplifier and a second transformer.

The first transformer is configured to carry out isolation and first power conversion on the output end of the phase shifter to obtain a first power signal.

The amplifier is configured to carry out second power conversion on the first power signal to obtain a second power signal.

The second transformer is configured to carry out isolation and third power conversion on the output end of the amplifier to obtain a second phase shift signal.

In embodiments of the disclosure, since the controller in the phase shifter can generate a control signal for controlling the adder based on a preset phase shift angle, the adder can carry out vector composing and phase compensation on the first orthogonal signal based on the control signal, that is, the phase compensation can be automatically realized without manually adjusting the current value of multi-channel, so that the debugging time is short, and the phase error can be controlled.

In some embodiments, the adder may include multiple signal processing units and an adder unit.

The input end of the signal processing units is connected with the output end of the orthogonal signal generator, the output end of the signal processing units is connected to the input end of the adder unit, and the signal processing units are configured to carry out amplitude adjustment and phase compensation on the first orthogonal signal.

The adder unit is configured to carry out additive operation on the first orthogonal signal after processing to obtain the first phase shift signal.

In some embodiments, the signal processing units may include an adjusting unit, and a phase compensation unit sequentially connected.

The adjusting unit is configured to carry out an amplitude adjustment on the first orthogonal signal.

The phase compensation unit is configured to carry out phase compensation on the first orthogonal signal after the amplitude adjustment.

In other embodiments, the signal processing units may also include a phase compensation unit, and an adjusting unit sequentially connected.

Embodiments of the disclosure provide another phase shifter, as shown in FIG. 3, which may include an orthogonal signal generator 301, an adjusting unit 302, a phase compensation unit 303, an adder unit 304 and a controller 305.

The output end of the orthogonal signal generator 301 is connected with the input end of the adjusting unit 302, and the orthogonal signal generator 301 is configured to generate a first orthogonal signal.

The controller 305 is connected to the adjusting unit 302, and the controller 305 is configured to generate a control signal based on a preset phase shift angle.

The output end of the adjusting unit 302 is connected to the input end of the phase compensation unit 303, and the adjusting unit 302 is configured to carry out an amplitude adjustment of the first orthogonal signal.

The output end of the phase compensation unit 303 is connected to the input end of the adder unit 304, and the phase compensation unit 303 is configured to carry out phase compensation on the first orthogonal signal after the amplitude adjustment.

The adder unit 304 is configured to carry out additive operation on the first orthogonal signal after processing to obtain the first phase shift signal.

In some embodiments, signal processing units may also include a phase compensation unit, and an adjusting unit sequentially connected.

The phase compensation unit is configured to carry out phase compensation on the first orthogonal signal.

The adjusting unit is configured to carry out an amplitude adjustment of the first orthogonal signal after the phase compensation.

In one possible embodiment, the angle of phase compensation may be determined according to the preset phase shift angle. The method for determining the angle of phase compensation according to the preset phase shift angle may include the following two modes.

Mode 1: the angle of phase compensation corresponding to the preset phase shift angle is determined according to the mapping relationship between the phase shift angle and the angle of phase compensation. For example, when the preset angle is 20 degrees, the angle of phase compensation may be 5 degrees, and when the preset angle is 30 degrees, the angle of phase compensation may be 6 degrees.

Mode 2: the angle of phase compensation is determined by a difference between a phase shift angle of the radio frequency signal output by the phase shifter and the preset phase shift angle acquired in real time. For example, in the case that the acquired difference between the phase shift angle of the radio frequency signal output by the phase shifter and the preset phase shift angle is 3 degrees, the angle of phase compensation is determined to be 3 degrees.

In embodiments of the disclosure, the adjusting unit in the adder can carry out an amplitude adjustment of the first orthogonal signal; the phase compensation unit in the adder performs phase compensation on the first orthogonal signal after the amplitude adjustment; the adder unit in the adder can perform additive operations on the processed first orthogonal signal to obtain a first phase shift signal, and the angle difference between the phase shift angle of the obtained first phase shift signal and the preset phase shift angle is smaller.

In some embodiments, the adjusting unit includes an orthogonal path selecting unit and a variable gain amplifier.

The input end of the orthogonal path selecting unit is connected with the output end of the orthogonal signal generator, and the orthogonal path selecting unit is configured to select a part of the first orthogonal signal.

The input end of the variable gain amplifier is connected with the output end of the orthogonal path selecting unit, and the variable gain amplifier is configured to adjust the amplitude of the selected part of the first orthogonal signal.

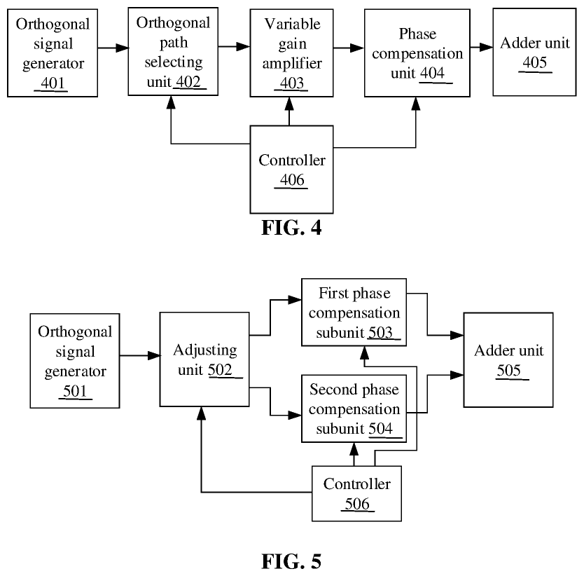

Embodiments of the disclosure provide yet another phase shifter, as shown in FIG. 4, which may include an orthogonal signal generator 401, an orthogonal path selecting unit 402, a variable gain amplifier 403, a phase compensation unit 404, an adder unit 405 and a controller 406.

The output end of the orthogonal signal generator 401 is connected with the first input end of the orthogonal path selecting unit 402, and the orthogonal signal generator 401 is configured to generate a first orthogonal signal.

The output end of the controller 406 is connected to the second input end of the orthogonal path selecting unit 402, and the controller 406 is configured to generate a control signal based on a preset phase shift angle.

The output of the orthogonal path selecting unit 402 is connected to the variable gain amplifier 403 and the orthogonal path selecting unit 402 is configured to select a part of the first orthogonal signal.

The output end of the variable gain amplifier 403 is connected to the input end of the phase compensation unit 404, and the variable gain amplifier 403 is configured to carry out an amplitude adjustment of the first orthogonal signal.

The output end of the phase compensation unit 404 is connected to the input end of the adder unit 405, and the phase compensation unit 404 is configured to carry out phase compensation on the first orthogonal signal after amplitude adjustment.

The adder unit 405 is configured to carry out additive operation on the first orthogonal signal after processing to obtain a first phase shift signal.

In embodiments of the disclosure, the orthogonal path selecting unit of the adjusting unit can select the polarity of the first orthogonal signal; and the variable gain amplifier can adjust the amplitude of the selected part of the first orthogonal signal.

In some embodiments, the variable gain amplifier may be a differential amplifier. In other embodiments, it may also be a single end amplifier.

In some embodiments, the first phase shift signal may be a differential signal, or a non-differential signal, which is specifically limited in the embodiments.

In some embodiments, the first orthogonal signal may include a multi-channel sub-signals. The first orthogonal signal may be four orthogonal signals (two positive output ends I+, Q+and two negative output ends I−, Q−); the first orthogonal signal may also be two orthogonal signals (a positive output end I+and a negative output end I−, or a positive output end Q+and a negative output end Q−, or a positive output end I+and a positive output end Q+), which is not specifically limited in the embodiments.

In some embodiments, the phase compensation unit has a compensation structure of at least one of “pi (π) type”, “T type”, or “L type”.

Embodiments of the disclosure further provide a phase shifter, as shown in FIG. 5, which may include an orthogonal signal generator 501, an adjusting unit 502, a first phase compensation subunit 503, a second phase compensation subunit 504, an adder unit 505 and a controller 506.

The output end of the orthogonal signal generator 501 is connected with the first input end of the adjusting unit 502, and the orthogonal signal generator 501 is configured to generate a first orthogonal signal.

The output of the controller 506 is connected to the second input end of the adjustment unit 502, and the controller 506 is configured to generate a first control signal for controlling the polarity and amplitude of the first orthogonal signal, a first sub-control signal for controlling the first phase compensation subunit 503, and a second sub-control signal for controlling the second phase compensation subunit 504 based on the preset phase shift angle.

The first output end of the adjusting unit 502 is connected to the input end of the first phase compensation unit 503. The second output end of the adjusting unit 502 is connected to the input end of the second phase compensation unit 504. The adjusting unit 502 is configured to select the polarity of the first orthogonal signal and adjust the amplitude of the first orthogonal signal based on the first control signal to obtain an I path sub-signal and a Q path sub-signal with a preset polarity and preset amplitude.

The output end of the first phase compensation subunit 503 is connected to the first input end of the adder unit 505, and the first phase compensation unit 503 is configured to carry out phase compensation on the I sub-signal based on the first sub-control signal, to obtain a third sub-signal.

The output end of the second phase compensation subunit 504 is connected to the second input end of the adder unit 505, and the second phase compensation unit 504 is configured to carry out phase compensation on the Q path sub-signal based on the second sub-control signal, to obtain a fourth sub-signal.

The adder unit 505 is configured to carry out additive operation on the third orthogonal signal to obtain the first phase shift signal.

It could be understood that, I path sub-signal and Q path sub-signal are orthogonal signals in the same orientation; and the I path sub-signal and the Q path sub-signal correspond to the real part and the imaginary part into which the complex signal is decomposed.

In one possible embodiment, the component structure of the first phase compensation unit and the second phase compensation unit may be the same.

It could be understood that the second orthogonal signal includes a first sub-signal of the I path and a second sub-signal of the Q path. The phase compensation unit includes a first phase compensation subunit for phase compensation of the first sub-signal and a second phase compensation subunit for phase compensation of the second sub-signal. The second control signal includes a first sub-control signal for controlling the first phase compensation subunit and a second sub-control signal for controlling the second phase compensation subunit. The third orthogonal signal includes a third sub-signal obtained by phase compensation for the first sub-signal and a fourth sub-signal obtained by phase compensation for the second sub-signal.

In embodiments of the disclosure, the first phase compensation unit performs phase compensation on the first sub-signal of the second orthogonal signal, and the second phase compensation unit performs phase compensation on the second sub-signal of the second orthogonal signal, so that symmetrical compensation on the differential signal can be realized and the phase compensation effect is good.

In an embodiment, the phase compensation unit includes at least one of an inductor or a capacitor.

It could be understood that, the voltage on the capacitor cannot change abruptly, and the current phase on the capacitor is 90 degrees ahead of the voltage phase. The current on the inductor cannot change abruptly, and the voltage phase on the inductor is 90 degrees ahead of the current phase.

In an embodiment, the phase compensation unit further includes at least one control switch in the case that every device in the phase compensation unit has a fixed reactance value.

It could be understood that, in order to realize automatic phase shifting for different preset phase shift angles, different phase shift angles need to be compensated for different preset phase shift angles, so it is necessary to automatically control the number of capacitors and inductors in the phase compensation unit. On the basis of this, a control switch can be arranged on a branch including a capacitor or an inductor, and the number of capacitors and inductors in the phase compensation circuit can be adjusted by controlling the control switch on and off, thereby adjusting the compensation angle of the phase compensation circuit.

In an embodiment, a compensation phase of the phase compensation unit is adjustable based on a gain and/or an output power of an amplifier connected to the adder unit.

On the basis of the above embodiments, embodiments of the disclosure further provide a phase shifting method, as shown in FIG. 6, which may include the following operations.

In S601: a first orthogonal signal is generated by an orthogonal signal generator.

In S602: a control signal for controlling the adder is generated by a controller generates based on a preset phase shift angle.

In S603: the amplitude of the first orthogonal signal is adjusted by an adder based on the control signal, and vector composing and phase compensation are carried out on the adjusted first orthogonal signal to obtain a first phase shift signal.

In one embodiment, the first phase shift signal is a signal with the same phase shift angle of the horizontal I path and the vertical Q path.

In S604, the power of the first phase shift signal is amplified by an amplifying circuit to obtain a second phase shift signal.

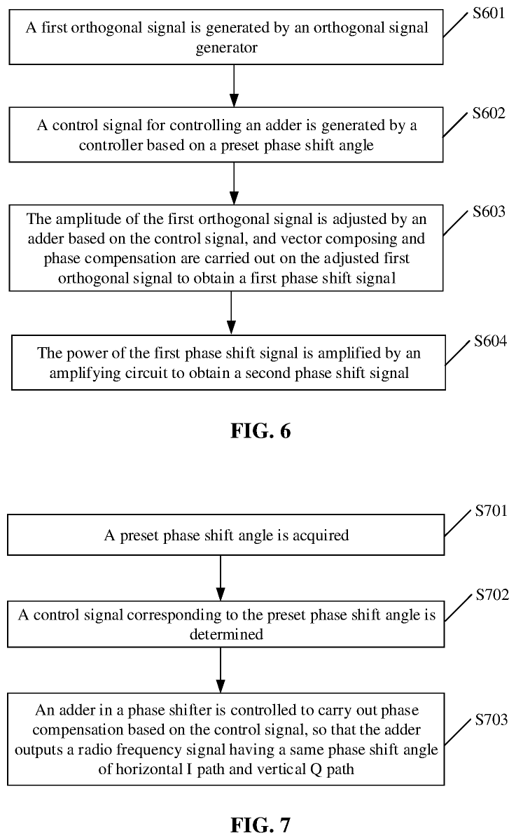

Embodiments of the disclosure further provide a phase shifting method, as shown in FIG. 7, which may include the following operations.

In S701, a preset phase shift angle is acquired;

In one embodiment, the preset phase shift angle may be acquired by receiving an artificial phase shift angle input and acquiring the preset phase shift angle in response to the phase shift angle input.

In another embodiment, the preset phase shift angle may be acquired by receiving externally input phase shift angle data through wired or wireless communication.

In S702, a control signal corresponding to the preset phase shift angle is determined.

It could be understood that there is a corresponding relationship between the preset phase shift angle and the control signal, and different preset phase shift angles correspond to different control signals.

In one possible embodiment, the control signal corresponding to the preset phase shift angle may be determined on the basis of the corresponding relationship between the phase shift angle and the control signal.

In S703, an adder in the phase shifter is controlled to carry out phase compensation based on the control signal, so that the adder outputs a radio frequency signal having a same phase shift angle of a horizontal I path and a vertical Q path.

In embodiments of the disclosure, the phase compensation is carried out on the adder in the phase shifter through the control signal corresponding to the preset phase shift angle, so that the adder outputs the radio frequency signal with equal phase shift, and the phase shift of the radio frequency signal with equal phase shift is closer to the preset phase shift angle, i.e., the phase shift accuracy is higher.

Embodiments of the disclosure provide another phase shifting method, which includes the following operations.

In S80, a preset phase shift angle is acquired;

In S81, a difference between the phase shift angle output by the phase shifter and the preset phase shift angle is acquired in real time.

In S82, a control signal corresponding to the preset phase shift angle is determined based on the difference.

It could be understood that there is a certain error between the phase shift angle output by the phase shifter without phase compensation and the preset phase shift angle. Therefore, the difference between the phase shift angle output by the phase shifter and the preset phase shift angle acquired in real time may serve as the compensation angle, and then the control signal corresponding to the compensation angle can be determined.

In S83, an adder in the phase shifter is controlled to carry out phase compensation based on the control signal, so that the adder outputs a radio frequency signal having a same phase shift angle of the horizontal I path and the vertical Q path.

In embodiments of the disclosure, the phase compensation is carried out on the adder of the phase shifter according to the control signal determined by the difference between the phase shift angle output by the phase shifter and the preset phase shift angle acquired in real time, so that the adder outputs the radio frequency signal with equal phase shift, and the phase shift of the radio frequency signal with equal phase shift is closer to the preset phase shift angle, i.e., the phase shift accuracy is higher.

Embodiments of the disclosure provide yet another phase shifting method, which includes the following operations.

In S91, a preset phase shift angle is acquired.

In S92, a mapping table of the phase shift angle and a compensation angle is acquired.

It could be understood that the mapping table of the phase shift angle and the compensation angle may be acquired by implementation or experience

In an embodiment, the mapping table of the phase shift angle and the compensation angle can be acquired by reading the mapping table of the phase shift angle and the compensation angle from a pre-stored database.

In S93, the compensation angle corresponding to the preset phase shift angle is determined based on the mapping table.

In an embodiment, the compensation angle corresponding to the preset phase shift angle can be searched based on the mapping table.

In S94, the control signal corresponding to the compensation angle is determined as the control signal corresponding to the preset phase shift angle.

In S95, an adder in the phase shifter is controlled to carry out phase compensation based on the control signal, so that the adder outputs a radio frequency signal having a same phase shift angle of I path and Q path.

In embodiments of the disclosure, the compensation angle corresponding to the preset phase shift angle is determined based on the mapping table of the phase shift angle and the compensation angle, and the adder in the phase shifter is controlled to carry out the phase compensation based on the control signal corresponding to the compensation angle, so that the adder outputs the radio frequency signal with equal phase shift, and the phase shift of the radio frequency signal with equal phase shift is closer to the preset phase shift angle, i.e., the phase shift accuracy is higher.

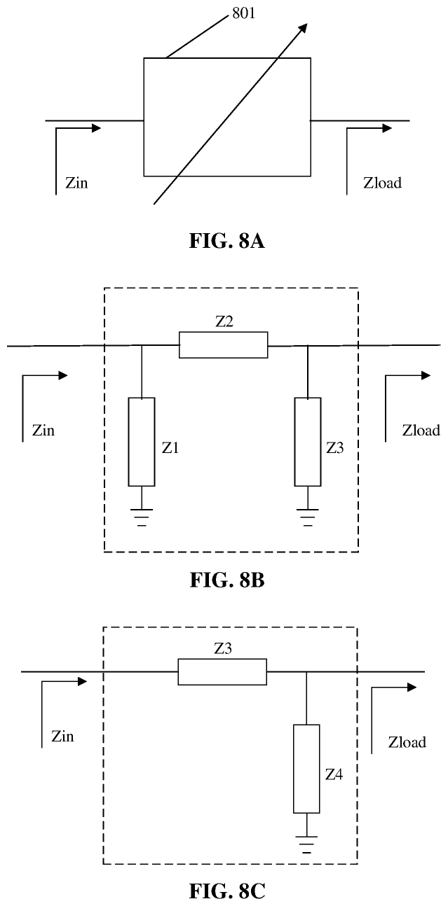

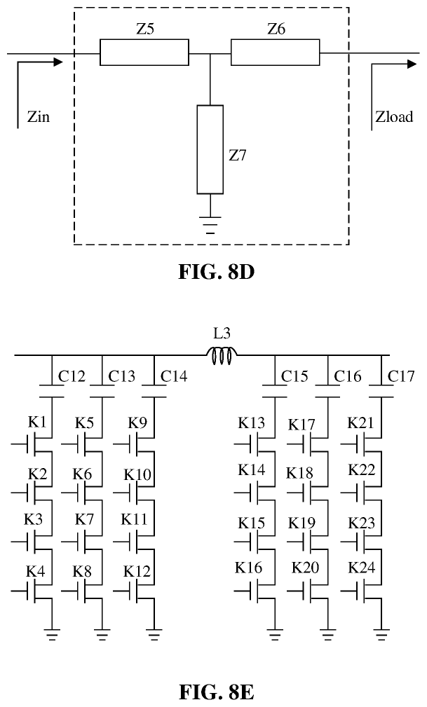

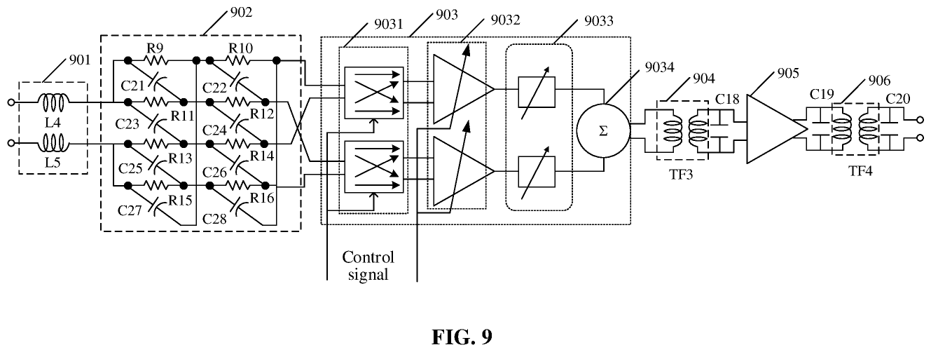

FIG. 8A is a component schematic diagram of a phase compensation unit provided by embodiments of the disclosure. As shown in FIG. 8A, the phase compensation unit may be an adjustable matching network 801. The adjustable matching network 801 is reasonably designed, so that by tuning the adjustable matching network 801, Zin can be adjusted to an impedance point that matches the load impedance Zload of the adjustable matching network 801 without adding additional matching network elements.

FIG. 8B is a schematic diagram of the component structure of a phase compensation unit provided by embodiments of the disclosure. As shown in FIG. 8B, Z1 is connected across the input end and the grounding end of the phase compensation unit; one end of Z2 is connected to the input end of the phase compensation unit, the other end of Z2 is connected to one end of Z3, and the other end of Z3 is connected to the grounding end. The common node of Z2 and Z3 is the output end of the phase compensation unit.

FIG. 8C is a schematic diagram of the component structure of another phase compensation unit provided by embodiments of the disclosure. As shown in FIG. 8C, a series branch formed by series connection of Z3 and Z4 is connected cross the input end and the grounding end of the phase compensation unit, and the common node of Z3 and Z4 serves as the output end of the phase compensation unit.

FIG. 8D is a schematic diagram of the component structure of yet another phase compensation unit provided by embodiments of the disclosure. As shown in FIG. 8D, a series branch formed by series connection of Z5 and Z6 is connected cross the input end and the output end of the phase compensation unit, the first end of Z7 is connected to the grounding end, and the other end of Z7 is connected to the common node of Z5 and Z6.

Here, Z1, Z2, Z3, Z4, Z5, Z6 and Z7 may be inductors, capacitors, resistors and transmission lines, and may be fixed reactance values or variable reactance values, at least one of which is a variable reactance value. Herein, the variable reactance may be realized by, but not limited to electrically modulated varactor, variable capacitor array, switching inductor or resistor array.

FIG. 8E is a circuit diagram of a phase compensation unit provided by embodiments of the disclosure. As shown in FIG. 8E, there are the third inductor L3, the twelfth capacitor C12 to the seventeenth capacitor C17, the first switch K1 to the twenty-fourth switch K24, in which C12 and K1 to K4 are connected in series to form a first series branch; C13 and K5 to K8 are connected in series to form a second series branch; C14 and K9 to K12 are connected in series to form a third series branch; C15 and K13 to K16 are connected in series to form a fourth series branch; C16 and K17 to K20 are connected in series to form a fifth series branch; C17 and K21 to K24 are connected in series to form a sixth series branch. The first parallel branch formed by parallel connection of the first to third series branches is connected cross the input end and the grounding end of the phase compensation unit; L3 is connected cross the input end and the output end of the phase compensation unit. A second parallel branch formed by parallel connection of the fourth to sixth series branches is connected cross the output end and the grounding end of the phase compensation unit. It can be seen that the capacitance value connected to the matching network can be changed by switching the switch on and off, thus changing the impedance of the matching network and achieving the function of adjustable matching.

FIG. 9 is a component circuit diagram of an active phase shifter provided by embodiments of the disclosure. As shown in FIG. 9, the active filter includes the inter stage matching network (IMN) 901, the PPF 902, the analog adder 903, the transformer TF3 904, the eighteenth capacitor C18, the amplifier 905, the nineteenth capacitor C19, the transformer TF4 906, and the twentieth capacitor C20, in which a constant amplitude differential radio frequency signal is input to the input end of the IMN 901, the IMN 901 performs network matching on the input constant amplitude differential radio frequency signal, and input the equal amplitude differential radio frequency signal after network matching into the PPF 902. The PPF 902 generates four orthogonal signals (two positive output ends I+, Q+and two negative output ends I−, Q−) with a same amplitude and 90-degree phase spacing. The four orthogonal signals with a same amplitude and 90-degree phase spacing are input to the analog adder 903. The analog adder 903 performs vector composing and phase compensation on the four orthogonal signals with a same amplitude and 90-degree phase spacing in response to an external control signal, and outputs the radio frequency signal with equal phase shift after phase compensation to the TF3 904. The TF3 904 performs isolation and first power conversion, and outputs a first power signal to the amplifier 905. The amplifier 905 performs second power conversion, and outputs the second power signal to the TF4 906. The TF4 906 performs isolation and third power conversion on the second power signal, and outputs the converted radio frequency signal with equal phase shift.

At the same time, C18 is connected cross the two input ends via the amplifier 905 for removing electromagnetic interference. C19 and C20 are connected cross the two input ends and two output ends of the TF4 906, respectively, for removing electromagnetic interference generated by TF4 906.

Here, the IMN 901 includes the fourth inductor L4 and the fifth inductor L5, L4 and L5 connected in series at the first input end and a second input end of the PPF 902, respectively. The PPF 902 is a two-order RC filter. The analog adder 903 includes an orthogonal path selecting unit 9031, a variable gain amplifier (VGA) 9032, a phase compensation unit 9033, and an adder 9034 that are sequentially connected.

It could be understood that the two-order RC filter includes eight resistors R9 to R16 and eight capacitors C12 to C28. Herein, a series branch formed by series connection of R9 and R10 is connected between the first input end and a first output end (I+) of the two-order RC filter; a series branch formed by series connection of R11 and R12 is connected between the first input end and a second output end (Q+) of the two-order RC filter; a series branch formed by series connection of R13 and R14 is connected between a second input end and a third output end (I−) of the two-order RC filter; a series branch formed by series connection of R15 and R16 is connected between the second input end and a fourth output end (Q−) of the two-order RC filter; C21 is connected across two ends of R11, and the positive electrode of C21 is connected on the first input end; the negative electrode of C22 is connected to the second output end, and the positive electrode of C22 is connected to the common node of R9 and R10; the positive electrode of C23 is connected to the first input end, and the negative electrode of C23 is connected to the common node of R13 and R14; the negative electrode of C24 is connected to the third output end, and the positive electrode of C24 is connected to the common node of R11 and R12; C25 is connected across two ends of R15, and the positive electrode of C25 is connected to the second input end; the negative electrode of C26 is connected to the fourth output end, and the positive electrode of C26 is connected to the common node of R13 and R614; the positive electrode of C27 is connected to the second input end, and the negative electrode of C27 is connected to the common node of R9 and R10; the negative electrode of C28 is connected to the first output end, and the positive electrode of C28 is connected to the common node of R15 and R16.

The above description of various embodiments tends to emphasize the differences between the various embodiments, the same or similarities of which may be referred to each other and will not be repeated herein for the sake of brevity.

The methods disclosed in various method embodiments provided by the disclosure may be combined arbitrarily without conflict to obtain new method embodiments.

The features disclosed in various product embodiments provided by the disclosure may be combined arbitrarily without conflict to obtain new product embodiments.

The features disclosed in various method or phase shifters provided by the disclosure may be combined arbitrarily without conflict to obtain new method or equipment embodiments.

Embodiments of the disclosure are described above in combination with the drawings; however, the disclosure is not limited to the above embodiments. The embodiments described above are merely illustrative and not restrictive. Many variants may be made by those skilled in the art with reference to this disclosure without departing from the spirit of this disclosure and protection scope of the claims, all of which fall within the protection of this application.

In the embodiments of the disclosure, since a controller in the phase shifter can generate a control signal for controlling the adder based on a preset phase shift angle, the adder can perform vector composing and phase compensation on the first orthogonal signal based on the control signal, that is, the phase compensation can be automatically realized without manually adjusting the current values of multi-channel, so that the debugging time is short, and the phase error can be controlled.

1. A phase shifter comprising an orthogonal signal generator and an adder;
an output end of the orthogonal signal generator being connected with an input end of the adder, and the orthogonal signal generator being configured to generate a first orthogonal signal;
the adder being configured to adjust amplitude of the first orthogonal signal, and to carry out vector composing and phase compensation on the adjusted first orthogonal signal to obtain a first phase shift signal.

2. The phase shifter according to claim 1, wherein the adder comprises multiple signal processing units and an adder unit,
an input end of the signal processing units is connected with the output end of the orthogonal signal generator, an output end of the signal processing units is connected to an input end of the adder unit, and the signal processing units are configured to carry out amplitude adjustment and phase compensation on the first orthogonal signal;
the adder unit is configured to carry out additive operation on the first orthogonal signal after processing to obtain the first phase shift signal.

3. The phase shifter according to claim 2, wherein the signal processing units comprise an adjusting unit and a phase compensation unit sequentially connected,
the adjusting unit is configured to carry out an amplitude adjustment on the first orthogonal signal;
the phase compensation unit is configured to carry out phase compensation on the first orthogonal signal after the amplitude adjustment.

4. The phase shifter according to claim 2, wherein the signal processing units comprise a phase compensation unit and an adjusting unit sequentially connected,
the phase compensation unit is configured to carry out phase compensation on the first orthogonal signal;
the adjusting unit is configured to carry out an amplitude adjustment on the first orthogonal signal after the phase compensation.

5. The phase shifter according to claim 3, wherein the phase compensation unit has a compensation structure of at least one of “pi (π) type”, “T type”, or “L type”.

6. The phase shifter according to claim 5, wherein the phase compensation unit comprises at least one of an inductor or a capacitor;
the phase compensation unit further comprises at least one control switch in a case that every device in the phase compensation unit has a fixed reactance value.

7. The phase shifter according to claim 3, wherein a compensation phase of the phase compensation unit is adjustable based on a gain and/or an output power of an amplifier connected to the adder unit.

8. The phase shifter according to claim 3, wherein the adjusting unit comprises:
an orthogonal path selecting unit, an input end of which is connected to the output end of the orthogonal signal generator, and the orthogonal path selecting unit is configured to select a part of the first orthogonal signal; and
a variable gain amplifier, an input end of which is connected with an output end of the orthogonal path selecting unit, and the variable gain amplifier is configured to adjust amplitude of the selected part of the first orthogonal signal.

9. The phase shifter according to claim 8, wherein the variable gain amplifier is a differential amplifier.

10. The phase shifter according to claim 1, wherein the first phase shift signal is a differential signal.

11. The phase shifter according to claim 1, wherein the first orthogonal signal comprises multi-channel sub-signals.

12. An amplifier assembly, comprising the phase shifter according to claim 1 and an amplifying circuit connected with an output of the phase shifter.

13. The amplifier assembly according to claim 12, wherein the amplifying circuit comprises a first transformer, an amplifier and a second transformer;
the first transformer is configured to carry out isolation and first power conversion on the output end of the phase shifter to obtain a first power signal;
the amplifier is configured to carry out second power conversion on the first power signal to obtain a second power signal;
the second transformer is configured to carry out isolation and third power conversion on an output end of the amplifier to obtain a second phase shift signal.

14. A phase shifting method comprising:
generating a first orthogonal signal by an orthogonal signal generator; and
adjusting amplitude of the first orthogonal signal by an adder, and carrying out vector composing and phase compensation on the adjusted first orthogonal signal to obtain a first phase shift signal.

15. A phase shifting method comprising:
acquiring a preset phase shift angle;
determining a control signal corresponding to the preset phase shift angle; and
controlling an adder in the phase shifter to carry out phase compensation based on the control signal, so that the adder outputs a radio frequency signal having a same phase shift angle of horizontal I path and vertical Q path.

16. The method according to claim 15, wherein the determining a control signal corresponding to the preset phase shift angle comprises:
acquiring a difference between a phase shift angle output by the phase shifter and the preset phase shift angle in real time;
generating a control signal corresponding to the preset phase shift angle based on the difference; or
acquiring a mapping table of the phase shift angle and a compensation angle;
determining the compensation angle corresponding to the preset phase shift angle based on the mapping table; and
determining a control signal corresponding to the compensation angle as the control signal corresponding to the preset phase shift angle.
